(19) United States
(12) Patent Application Publication
(10) Pub. No.: US 2011/0304758 A1
(43) Pub. Date: Dec. 15, 2011

(54) HIGH SPEED IMAGING THROUGH IN-PIXEL STORAGE

(76) Inventors: Munir Eldesouki, Hamilton (CA); Mohamed Jamal Deen, Dundas (CA); Qiyin Fang, Grimsby (CA)

(21) Appl. No.: 12/814,443

(22) Filed: Jun. 12, 2010

(51) Int. Cl. H04N 5/335; H01L 27/146

(52) U.S. Cl. 348/308; 250/208.1; 348/E05.091

(57) ABSTRACT

Disclosed are a system, a method and an apparatus of high speed imaging through in-pixel storage. In one embodiment, an image sensor includes an event sensor to detect events in a process. In addition, the image sensor includes an in-pixel storage to increase an event capture rate of the events through a separation of an event capture operation from other operations of the image sensor.

### FIELD OF TECHNOLOGY

This disclosure relates generally to a technical field of electronic circuits and, in one example embodiment, to a system, method and an apparatus of high speed imaging through in-pixel storage.

### BACKGROUND

An ability of the event capture device to operate at the threshold event capture rate may be constrained because a circuit to implement the event capture device may be implemented on a slow (>130 nm deep sub micron) semiconductor technology. An ability of the event capture device to operate the threshold event capture rate may also be constrained because a bottleneck may be created in an event capture operation. The event capture operation may include three consecutive phases. The three consecutive phases may be a capture of the event, a conversion of the captured event to a format that can be processed by the event capture device (e.g., digital format from a non digital format), and a reading out of the captured event from the event capture device after conversion. The reading out phase of the event capture operation may take longest time to execute because of a limited number of an input and output ports available on the event capture device. The input and output ports on the event capture device may be used to readout the events after they are converted to a format that can be processed by the event capture device.

Since each event capture goes sequentially through the three phases that occur consecutively in the order of capture, convert and readout, the delay in the readout and convert phases may create a bottleneck in the time between consecutive capture of events. Alternately, the bottleneck may be created because the operations of the three consecutive phases are not independent of each other. For example, if an event capture device hypothetically takes 10 s to capture the event, 10 s to convert the captured image to a digital format and 30 s to readout the image from the event capture device after conversion, the time taken between two consecutive captures of events is 50 s. In the example, if the event capture device may be used to capture events of a process in which the events occur at a rate higher than 1 event per 50 s, then the event capture device is not be able to capture the change in events that occurs during the convert and readout phase between each capture. The bottleneck created by the delay in conversion and readout phase may prevent the event capture device from operating at sub micro or nanosecond event capture speeds making it unsuitable for high speed processes.

### SUMMARY

Disclosed are a system, a method and an apparatus of high speed imaging through in-pixel storage. In one aspect, an image sensor includes an event sensor to detect events in a process. In addition, the image sensor includes an in-pixel storage to increase an event capture rate of the events through a separation of an event capture operation from other operations of the image sensor. The other operations may include a conversion operation and a readout operation of the image sensor.

The image sensor may include a first buffer circuit to transfer detected events from the event sensor to the in-pixel storage. The buffer circuit may accumulate light energy for a threshold amount of time before transfer to the in-pixel storage. The image sensor may also include a second buffer circuit to transmit data in the in-pixel storage to an output circuit. In addition, the image sensor may include a reset circuit to reset the event sensor between subsequent events when a setting of a voltage of the event sensor is changed to a high reset voltage.

In addition, the image sensor may include a first clear circuit to reset the second buffer circuit between subsequent transmissions of the data in the in-pixel storage to the output circuit. The output circuit may communicate the accumulated light energy to an external source. The accumulated light energy may be stored in a capacitor. The capacitor may be created from thick oxide MOS processes. The thick oxide processes may reduce a leakage of the storage capacitor and the MOS device to reduce a layout area of the image sensor.

The in-pixel storage may place the accumulated light energy in an additive form such that the addition of a subsequent light energy to enhance a characteristic of an image generated through the image sensor in the case of low light levels. The in-pixel storage may include a write circuit of the storage circuit to operate as a global shutter when the accumulated light energy is stored. The in-pixel storage may also include a second clear circuit of the storage circuit to clear the accumulated light energy stored in the write circuit. In addition, the in-pixel storage may also include a read circuit of the storage circuit to access the accumulated light energy that is stored in the write circuit.

The event sensor may be a photodiode used in an n+/p− well with a guard ring to increase a speed of the photodiode. Alternatively, the event sensor may also be an avalanche photodiode that can provide high gain and high speed allowing for reduced object illumination. The photodiode may occupy a layout area in the image sensor that reduces a fill factor of the image sensor to around 9%. The image sensor may be formed through an array of pixel sensors units. The image sensor may be an active pixel sensor.

The events in the process may include eight analog frames. The eight frames may be stored in different memory units of the in-pixel storage. The Image sensor as described herein may be implemented in a CMOS circuit using 130 nanometer deep sub-micron technology. The capturing of the eight analog frames may be implemented at a speed of the 130 nanometer deep sub-micron technology operating speed. The image sensor may operate at sub-nanosecond speeds.

In another aspect, a method of an image sensor includes capturing n-number of analog frames. In addition, the method of the image sensor includes storing the n-number of the analog frames in an in-pixel storage. The method of the image sensor also includes converting each of the n-number of the analog frames to digital frames. The method of the image sensor further includes reconstructing an event change through an ordering of the digital frames.

In yet another aspect, a system includes a rapidly moving object. In addition, the system includes an image sensor device to detect events in a process of movement of the rapidly moving object, and to increase an event capture rate of the events of the rapidly moving object through a separation of an event capture operation from other operations of the image sensor using multiple in-pixel storage modules.

The methods, systems and apparatuses disclosed herein may be implemented in any means for achieving various aspects, and may be executed in a form of a machine-readable medium embodying a set of instructions that, when executed by a machine, cause the machine to perform any of the operations disclosed herein. Other features will be apparent from the accompanying drawings and from the detailed description that follows.

### BRIEF DESCRIPTION OF THE VIEWS OF DRAWINGS

Example embodiments are illustrated by way of example and not limitation in the figures of accompanying drawings, in which like references indicate similar elements and in which:

FIG. 1A is a circuit view of an image sensor that includes in-pixel storage unit(s) configured to hold eight frames, according to one or more embodiments.

FIG. 1B is a layout view illustrating an implementation of the image sensor of FIG. 1, according to an example embodiment,

FIG. 2 is a schematic view illustrating the image sensor with a single in-pixel storage unit, according to one or more embodiments.

FIG. 3 is a schematic view illustrating a write operation performed in the in-pixel storage unit of FIG. 2, according to one or more embodiments.

FIG. 4 is a schematic view illustrating a read operation performed in the in-pixel storage unit of FIG. 2, according to one or more embodiments.

FIG. 5 is a schematic view illustrating a memory clear operation performed in the in-pixel storage unit, according to one or more embodiments.

FIG. 6 is a schematic view illustrating an array of pixels (e.g., image sensors and memory units), according to one or more embodiments.

FIG. 7 is a table view illustrating comparison between various image processing technologies using different types of pixel arrays, according to one embodiment.

Other features of the present embodiments will be apparent from accompanying Drawings and from the Detailed Description that follows.

### DETAILED DESCRIPTION

Disclosed are a system, a method and an apparatus of high speed imaging through in-pixel storage. It will be appreciated that the various embodiments discussed herein need not necessarily belong to the same group of exemplary embodiments, and may be grouped into various other embodiments not explicitly disclosed herein. In the following description, for purposes of explanation, numerous specific details are set forth in order to provide a thorough understanding of the various embodiments.

High speed image processing may include several stages. Broadly describing, the stages may include an image acquisition operation, a conversion operation and a readout operation. The image acquisition phase is a phase where frames are acquired at a various acquisition rates. The conversion phase is a phase where analog information from the acquisition phase is converted into digital information and the readout phase is a phase where the digital information is readout from a processing unit. All these stages are performed using respective circuitry units in imaging devices (e.g., camera). Embodiments described herein discusses about performing high speed image processing using an image sensor by performing the image acquisition phase independent of the other phases such as the conversion phase and the readout phase. In addition, the image sensor as described herein is configured for simultaneous pixel counting to improve the frame rate and to simplify pixel (e.g., image sensor and memory design) and to increase a fill-factor.

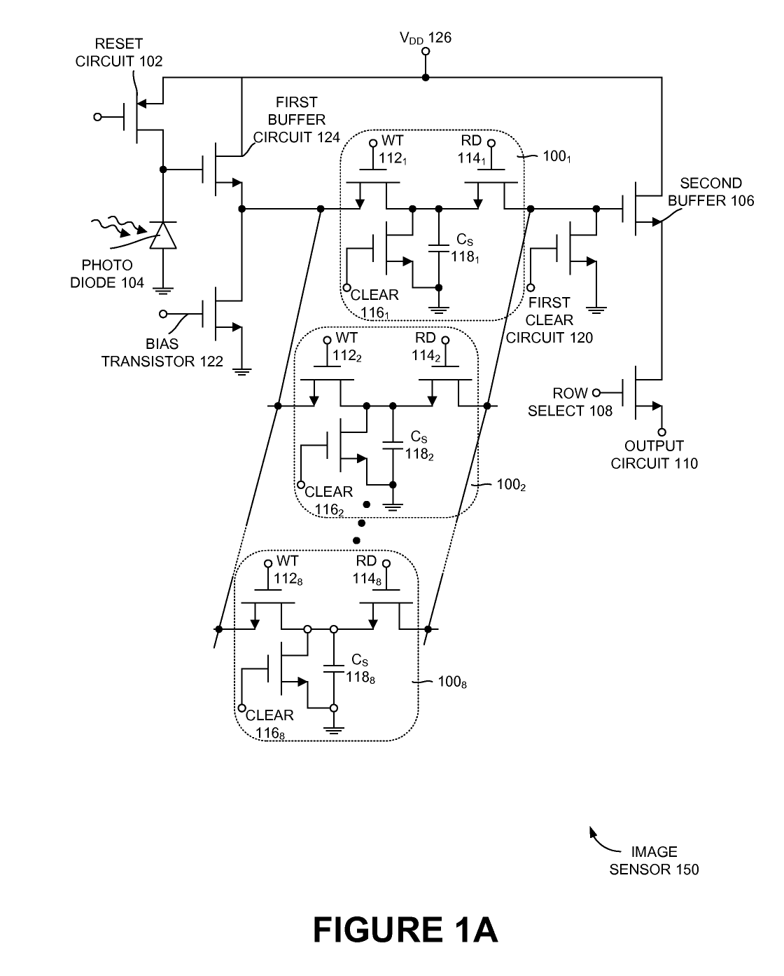

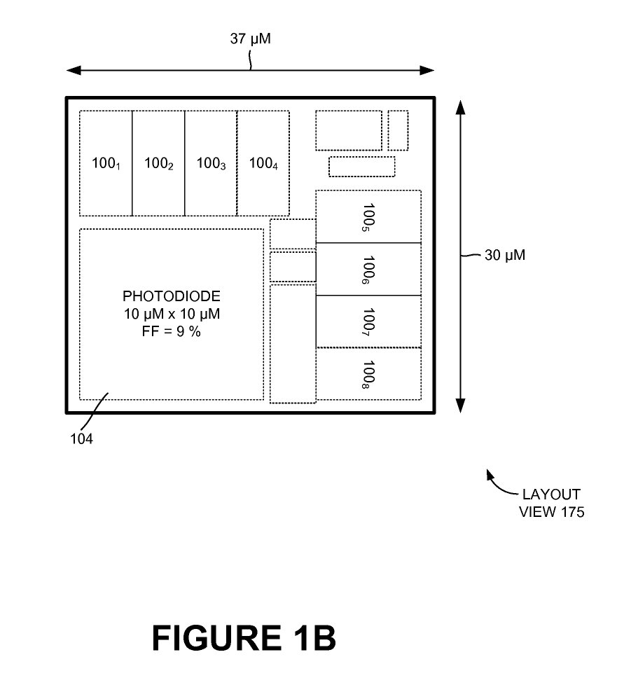

FIG. 1A is a circuit view of an image sensor 150 that includes in-pixel storage unit(s) 100₁₋₈ to hold eight frames at a high speed, according to one or more embodiments. In one or more embodiments, the image sensor 150 as described herein may include in-pixel storage unit(s) 100₁₋₈ (e.g., analog memory unit(s)), a reset circuit 102, an avalanche photodiode 104, a second buffer 106, a row select 108, an output 110, a first clear circuit 120, the bias transistor 122, a first buffer circuit 124, and a V_{DD} input 126. Although, the image sensor 150 as described herein one embodiment has eight in-pixel storage unit(s) 100₁₋₈, the image sensor 150 can also be designed with ‘N’ number of in-pixel storage unit(s), where ‘N’ is a positive integer.

In one or more embodiments, the image sensor 150 as described herein may be implemented in a deep-submicron complementary metal oxide semiconductor (CMOS) 130 nanometer technology for high speed operation, thereby enabling the image sensor 150 to operate at sub-nanosecond speeds. In one or more embodiments, the image sensor 150 may be an Active-Pixel Sensor (APS). In one or more embodiment, the image sensor 150 as described may be designed to include eight in-pixel storage unit(s) 100₁₋₈ to temporarily hold eight frames at a very high speed. The eight in-pixel storage unit(s) 100₁₋₈ may include write control(s) 112₁₋₈, read control(s) 114₁₋₈, a second clear circuit (clear 116₁₋₈), and capacitor(s) 118_{1-N}. In one or more embodiments, the write control(s) 112₁₋₈, read control(s) 114₁₋₈, and the clear 116₁₋₈ may be implemented using transistors. In one embodiment, the write control(s) 112₁₋₈, read control(s) 114₁₋₈, clear control(s) 116₁₋₈ as described herein are implemented using high speed n-channel enhancement-type MOSFET (NMOS) transistors. In one or more embodiments the image sensor 150 may be provided with a V_{DD} supply 126. Also, in one embodiment, the storage capacitor(s) 118_{1-N} of the analog memory units may be implemented using MOS capacitors using thick-oxide devices to reduce charge leakage and to reduce layout area. Layout design 175 of the image sensor 150 as an example embodiment is illustrated in FIG. 1B. In one or more embodiments, the row select 108 enables selecting a pixel values from a row in the pixel array.

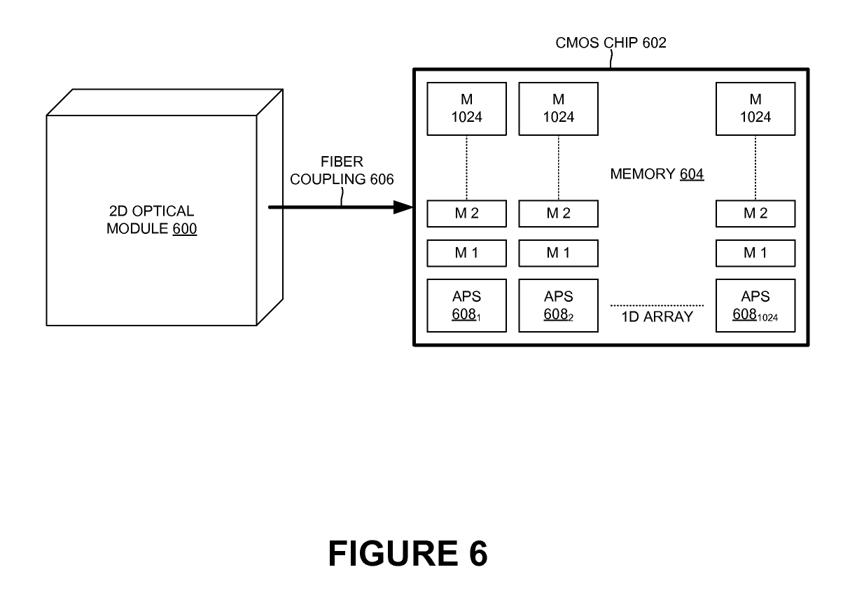

In one or more embodiments, the image sensor 150 as described herein is configured to detect events in a process through an event sensor (e.g., CMOS avalanche photodiode 104). The events may be a change in environment such as change in a content of the place, rapidly moving object, change in position of object, change in location of the object, change in shape of object. In one or more embodiments, the image sensor 150 to detect an event may be a CMOS image sensor (e.g., avalanche photodiode 104). Also, the image sensor 150 as described herein may include event sensor(s) and in-pixel storage units 100₁₋₈ (e.g., in-situ memory units). In one or more embodiments, the image sensor 150 may be configured to capture the events in ‘N’ number of frames through an event sensor (e.g., the avalanche photodiode 104). However, in one example embodiment, the image sensor 150 as described herein is configured to capture eight (analog) frames at an acquisition rate of 1.25 billion Frames Per Second (fps). Although, the image sensor 150 as described is configured for capturing eight frames per second, the image sensor 150 can also be configured to capture ‘N’ number of frames by slight modification in design of image sensor 150 as illustrated in FIG. 6.

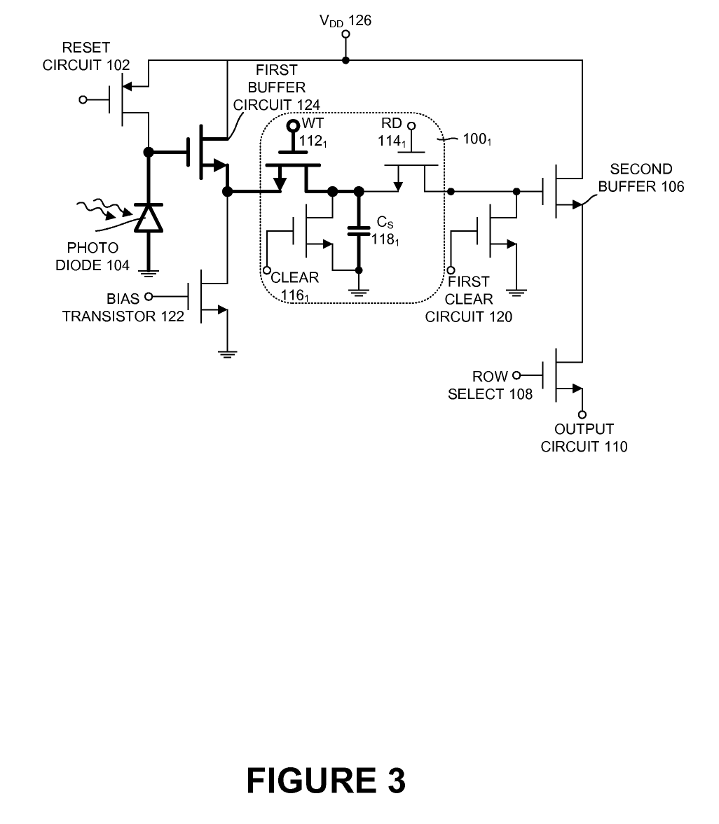

The captured ‘N’ frames may be stored in an in-pixel storage unit(s) 100 and processed further as described in FIG. 3-5. In one or more embodiments, the in-pixel storage unit(s) 100 which are designed to be a part of image sensor may enable holding frames at a higher rate. In one or more embodiments, the captured frames (e.g., events) are stored in the in-pixel storage units instead of processing the captured frames, thereby enabling the image sensor 150 to capture more frames without much delay. The captured frames (e.g., events) are stored in the in-pixel memories as light energy (e.g., stored as a charge) and then readout through the output buffer 106 for further processing in other phases such as the conversion phase and the readout phase.

FIG. 1B is a layout view 175 illustrating an implementation of the image sensor 150 in a chip, according to an example embodiment. In the example embodiment, the chip is designed and constructed in an area of 37 Micrometer×30 Micrometer. The avalanche photodiode 104 or an event sensor is implemented in 10 Micrometer×10 Micrometer providing a fill factor of about 9%. Also, in the example embodiment, the avalanche photodiode 104 being used is an n+/p-well with a ring guard which increases a speed of the avalanche photodiode 104 by eliminating slowly diffusing substrate carriers. In the example embodiment, FIG. 1B illustrates a layout design that includes interalia, eight in-pixel storage units 100₁₋₈, and the avalanche photodiode 104.

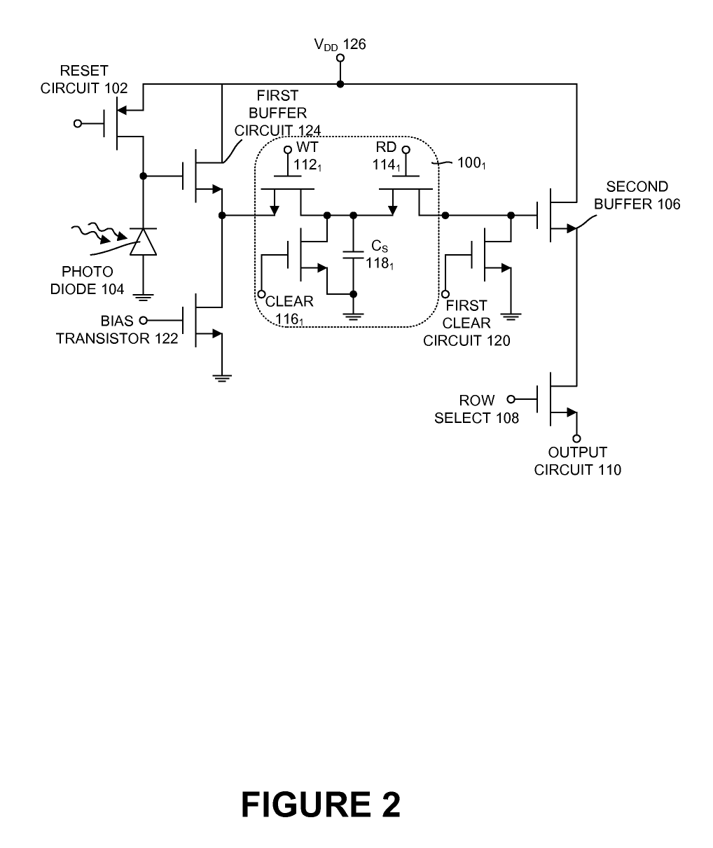

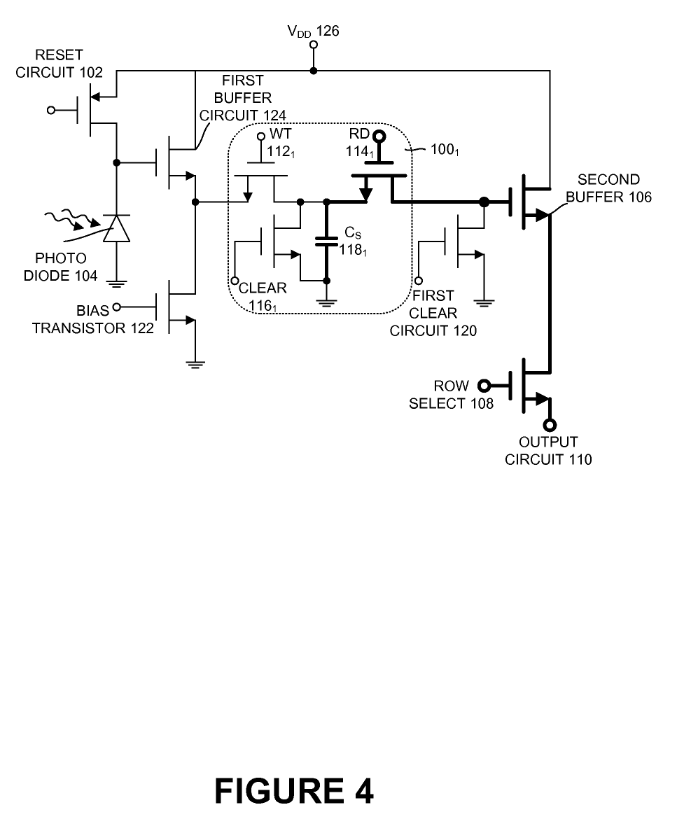

FIG. 2 is a schematic view illustrating the image sensor 150 with a single in-pixel storage unit 100₁, according to one or more embodiments. Initially the image sensor 150 may be reset using the reset circuit 102 to clear the contents/charge in the image sensor 150. In addition, in one or more embodiments, the reset circuit 102 may also be configured to reset the image sensor between subsequent events. In an example embodiment, the image sensor 150 is reset initially and between the subsequent events when a setting of a voltage of the avalanche photodiode 104 is changed to a high reset voltage. Also, the first clear circuit 120 of the image sensor device 150 may be used to reset the second buffer circuit 106 between subsequent transmissions of the data in the in-pixel storage units 100₁₋₈ to the output circuit 110. In one or more embodiments, the reset circuit 102 and the second buffer circuit may be implemented using a NMOS transistor. FIGS. 3-4 illustrates the operation of the image sensor 150 of FIG. 2, according to one or more embodiments.

FIG. 3 is a schematic view illustrating a write operation performed in the in-pixel storage unit 100₁ of FIG. 2, according to one or more embodiments. The avalanche photodiode 104 or the event sensor of the image sensor 150 may be configured to detect events in a process. In one or more embodiments, the process may be an ultra high speed process such as a ballistic analysis, a rapid moving object and bio-mechanics process. In one or more embodiments, the events may be captured through the avalanche photodiode 104 in a form of frames. Further, the detected events (e.g., in form of captured frames) may be communicated to the in-pixel storage unit(s) 100₁₋₈ through the first buffer circuit 124. In one or more embodiment, the first buffer circuit 124 (e.g., a NMOS transistor) chosen for the circuit may be capable of accumulating light energy (e.g., in a form of charge) for a threshold amount of time before being enabled to communicate to the in-pixel storage unit 100₁. In one or more embodiments, the write circuit 112₁ of the in-pixel storage unit 100₁ may be configured to allow the captured frames in a form of charge to be stored in the capacitor 118₁.

Furthermore, in one or more embodiment, the captured frames (e.g., accumulated light energy in form of chargers) may be stored in the capacitor 118₁ of the in-pixel storage unit(s) (e.g., the analog memory). In one or more embodiments, the in-pixel storage units 100₁₋₈ are designed to increase an event capture rate of events. In one or more embodiments, the capacitor 118₁ may be a MOS capacitor implemented using thick-oxide devices to reduce charge leakage. In one or more embodiments, the in-pixel storage unit 100₁₋₈ may be configured such that the in-pixel storage unit 100₁₋₈ can store charges in an additive form (e.g., accumulation due to subsequent frames) such that the addition of the subsequent light energy enhances a characteristic of an image generated through the image sensor 150 in the case of low light levels.

FIG. 4 is a schematic view illustrating a read operation performed in the in-pixel storage unit 100₁ of FIG. 2, according to one or more embodiments. In one or more embodiments, when the read circuit 114₁ of the in-pixel storage unit 100₁ is enabled, the light energy in the form of charge is discharged into the second buffer 106. Similar to the first buffer circuit 124, the second buffer circuit 106 is also configured to hold the light energy for a threshold amount of time. Once the output circuit is enabled 110 through the row select 108 bias, the light energy in a form of charge in the second buffer circuit 106 may be discharged through the output circuit 110.

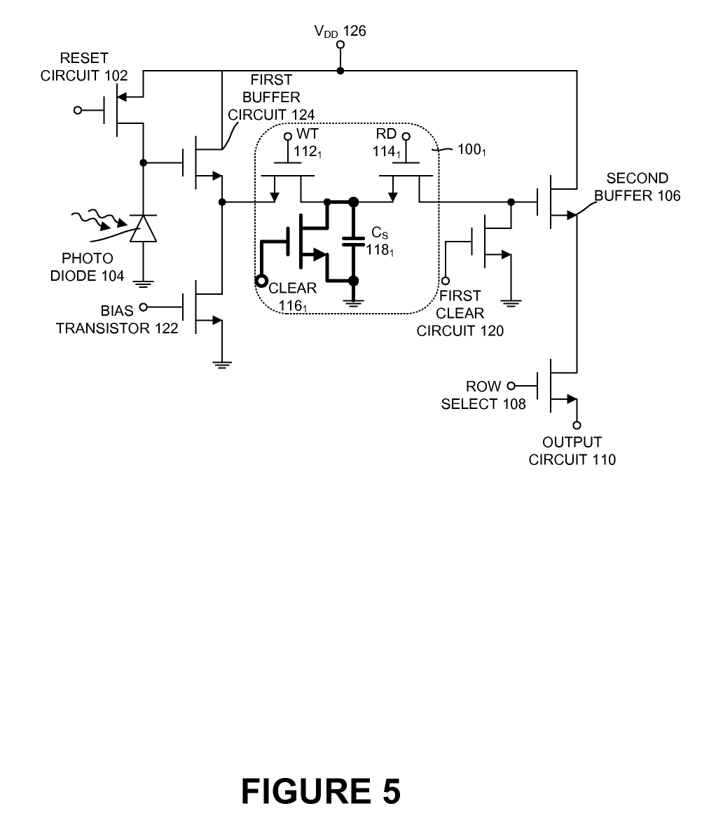

FIG. 5 is a schematic view illustrating a memory clear operation performed in the in-pixel storage unit 100₁, according to one or more embodiments. In one or more embodiments, the second clear circuit (clear 116₁) may be provided in the in-pixel storage unit 100₁ to clear the accumulated light energy stored in the capacitor 118₁. In one or more embodiments, the clear 116₁ (e.g., a NMOS transistor) when enabled discharges the light energy in the capacitor 118₁ through the clear 116₁.

The read/write/clear operations as described in FIG. 3-5 are not limited to in-pixel storage unit 100₁, but are applicable to all the ‘N’ number of in-pixel storage units and particularly to the in-pixel storage units 100₁₋₈ as in the example embodiment.

In one or more embodiments, the number of frames that can be captured consecutively can be increased by including an array of image sensors in the CMOS chip 602. An example embodiment is illustrated in FIG. 6 with an array of 1024 image sensors (APS 608₁₋₁₀₂₄). In the example embodiment, a 1D line-scan imager may be used where an imaging array is arranged into an array of 1024 APS pixels. Each APS pixel may include an array of 1024 in-pixels storage units (e.g., represented as ‘M’ in Figure). In addition, a 2D optical module may be coupled to the CMOS chip 602 through a fiber coupling 606 to achieve ultrahigh-speed imaging without sacrificing array fill-factor (FF). In one or more embodiments, the fraction of the area occupied by the photo detector (e.g., the avalanche photodiode 104) in a pixel (e.g., the image sensor), compared to the total area of the image sensors may be known as the fill-factor (FF).

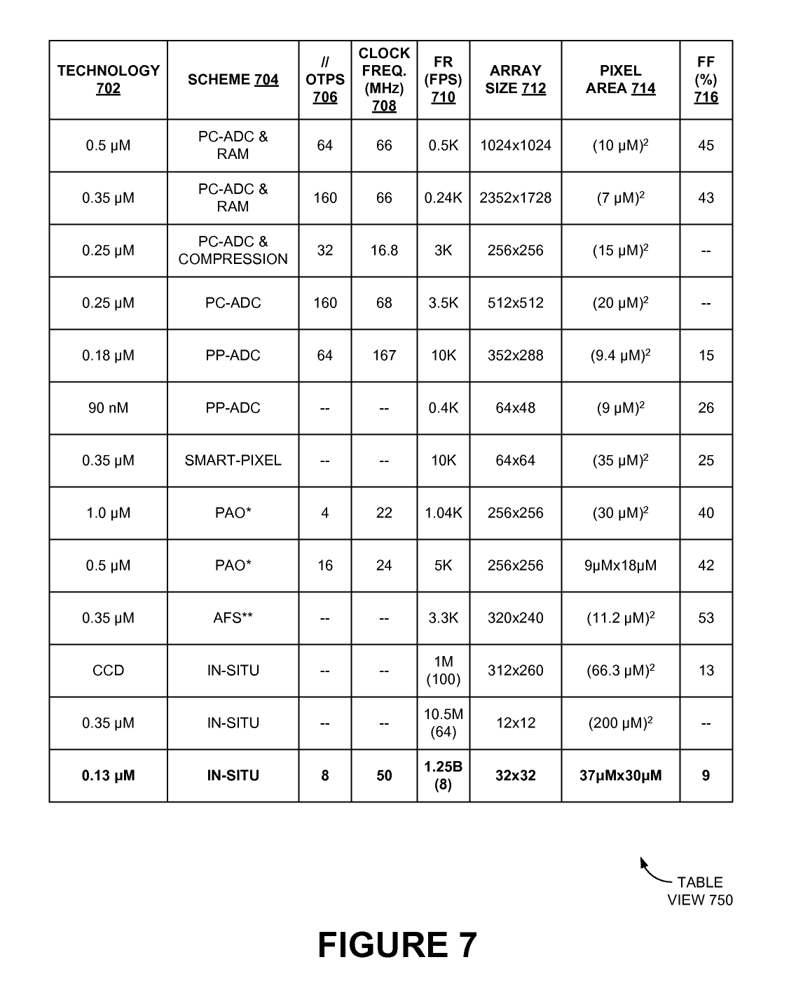

FIG. 7 illustrates a table which provides comparison between various image processing technologies using different types of pixel arrays, according to one embodiment. A technology 702 column illustrates information about the CMOS technology used, a scheme 704 column illustrates information about the architecture used, OTPS 706 column illustrates information about the number of parallel outputs, a clock frequency 708 column illustrates information about clock frequency used by each of the architecture in Megahertz (MHz), a FR 710 column illustrates information about frame rate achieved by each of the architectures, an array size 712 column illustrates information about array size of sensor in each of the architectures, a pixel area 714 column illustrates information about area covered by image sensors with memory in each of the architectures and a FF percentage 716 column illustrates information about percentage of fill-factor in each of the architectures. The last row illustrates the information of the image sensor described herein one embodiment. Technology of the image sensor 150 is implemented in 0.13 micrometer. The memory units (in-pixel storage units 100_{1-N}) are in extraction phase itself.

The image sensor 150 as described herein may be used in several applications. Specifically the image sensor 150 may be used in applications that require capturing events in a short pulse of time. For example, the image sensor 150 can be used for biomedical applications such as fluorescence lifetime imaging (FLIM) that can provide pre-cancer diagnosis. FLIM may require capturing a lifetime decay curve within 10-20 nanoseconds which currently, no imager can achieve. Existing FLIM techniques rely on hundreds of repetitive experiments, capturing one sample per experiment and delaying the starting point before repeating the next experiment. The process using the existing FLIM techniques may take a long time, cause inaccuracy due to non-identical experiments and is expensive. The image sensor 150 as described herein may be implemented in such application that enables for reconstructing a FLIM curve in one experiment.

Also, in another example, the image sensor 150 as described herein may be used for high energy physics experiments and nuclear testing, where experiments cannot be repeatable. Other applications include ballistic analysis, bio-mechanics, etc.

Although the present embodiments have been described with reference to specific example embodiments, it will be evident that various modifications and changes may be made to these embodiments without departing from the broader spirit and scope of the various embodiments. For example, the various devices and modules described herein may be enabled and operated using hardware circuitry (e.g., CMOS based logic circuitry), firmware, software or any combination of hardware, firmware, and software (e.g., embodied in a machine readable medium). For example, the various electrical structure and methods may be embodied using transistors, logic gates, and electrical circuits (e.g., application specific integrated (ASIC) circuitry and/or in Digital Signal Processor (DSP) circuitry).

In addition, it will be appreciated that the various operations, processes, and methods disclosed herein may be embodied in a machine-readable medium and/or a machine accessible medium compatible with a data processing system (e.g., a computer system), and may be performed in any order (e.g., including using means for achieving the various operations). Accordingly, the specification and drawings are to be regarded in an illustrative rather than a restrictive sense.

What is claimed:

1. An image sensor, comprising:
an event sensor to detect events in a process; and
an in-pixel storage to increase an event capture rate of the events through a separation of an event capture operation from other operations of the image sensor.

2. The image sensor of claim 1 wherein the other operations include a conversion operation and a readout operation of the image sensor.

3. The image sensor of claim 1 further comprising:
a first buffer circuit to transfer detected events from the event sensor to the in-pixel storage, wherein the buffer circuit to accumulate light energy for a threshold amount of time before transfer to the in-pixel storage; and
a second buffer circuit to transmit data in the in-pixel storage to an output circuit.

4. The image sensor of claim 3 further comprising:
a reset circuit to reset the event sensor between subsequent events when a setting of a voltage of the event sensor is changed to a high reset voltage; and
a first clear circuit to reset the second buffer circuit between subsequent transmissions of the data in the in-pixel storage to the output circuit.

5. The image sensor of claim 4 wherein the output circuit to communicate the accumulated light energy to an external source.

6. The image sensor of claim 5 wherein the accumulated light energy is stored in a capacitor, wherein the capacitor is created from thick oxide MOS processes, wherein the thick oxide processes to reduce a leakage of the storage capacitor and the MOS device to reduce a layout area of the image sensor.

7. The image sensor in claim 5, wherein the in-pixel storage to place the accumulated light energy in an additive form such that the addition of a subsequent light energy to enhance a characteristic of an image generated through the image sensor, wherein the image is a low light level image.

8. The image sensor in claim 7, wherein the in-pixel storage further comprising:
a write circuit of the storage circuit to operate as a global shutter when the accumulated light energy is stored,
a second clear circuit of the storage circuit to clear the accumulated light energy stored in the write circuit, and
a read circuit of the storage circuit to access the accumulated light energy that is stored in the write circuit.

9. The image sensor in claim 1, wherein the event sensor is a photodiode used in a n+/p− well with a guard ring to increase a speed of the photodiode.

10. The image sensor in claim 1, wherein the event sensor can also be an avalanche photodiode that can provide high gain and high speed allowing for reduced object illumination.

11. The image sensor in claim 9, wherein the photodiode occupies a layout area in the image sensor that reduces a fill factor of the image sensor to at most 9%.

12. The image sensor of claim 1 wherein the image sensor is formed through an array of pixel sensors units, wherein the image sensor is an active pixel sensor.

13. The image sensor of claim 1 wherein the events in the process comprise at least eight analog frames.

14. The image sensor of claim 13 wherein the at least eight frames are stored in different memory units of the in-pixel storage.

15. The image sensor of claim 1 wherein image sensor is implemented in a CMOS circuit using 130 nanometer deep sub-micron technology.

16. The image sensor of claim 15 wherein the capturing of the at least eight analog frames operate at a speed at least that of the 130 nanometer deep sub-micron technology operating speed.

17. The image sensor of claim 1 wherein the image sensor to operate at sub-nanosecond speeds.

18. A method of an image sensor comprising:
capturing n-number of analog frames;
storing the n-number of the analog frames in an in-pixel storage;
converting each of the n-number of the analog frames to digital frames; and
reconstructing an event change through an ordering of the digital frames.

19. The method of claim 18 wherein the n-number of analog frames are at least eight analog frames.

20. The method of claim 19 wherein the at least eight frames are stored in different memory units of the in-pixel storage.

21. The method of claim 18 wherein the method is implemented in a CMOS circuit using a deep sub-micron technology, wherein the deep submicron technology channel length to be no greater than 130 nanometer.

22. The method of claim 21 wherein the capturing of the n-number of non-digital frames operate at a speed at least that of the 130 nanometer deep sub-micron technology operating speed.

23. The method of claim 22 wherein the image sensor to operate at sub-nanosecond speeds.

24. A system comprising, comprising:
a rapidly moving object; and
an image sensor device to detect events in a process of movement of the rapidly moving object, and to increase an event capture rate of the events of the rapidly moving object through a separation of an event capture operation from other operations of the image sensor using multiple in-pixel storage modules.

25. The system device of claim 24 wherein the rapidly moving object exhibits properties of a fluorescence lifetime curve.

26. The system of claim 24 further comprising:
a first buffer module of the image sensor device to transfer detected events from an event sensor to the in-pixel storage module, wherein a buffer module to accumulate light energy for a threshold amount of time before transfer to the in-pixel storage module;
a second buffer module of the image sensor device to transmit data in the in-pixel storage module to an output module;
a reset module of the image sensor device to reset the event sensor between subsequent events when a setting of a voltage of an event sensor is changed to a high reset voltage; and
a first clear module of the image sensor device to reset the second buffer module between subsequent transmissions of the data in the in-pixel storage module to the output module.
